(19) United States
(12) Patent Application Publication
(10) Pub. No.: US 2005/0206981 A1
(43) Pub. Date: Sep. 22, 2005

(54) METHOD AND APPARATUS FOR IMPROVING QUALITY OF SCANNED IMAGE THROUGH PREVIEW OPERATION

(76) Inventor: Yueh-Chi Hung, Taipei Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/906,976

(22) Filed: Mar. 15, 2005

(30) Foreign Application Priority Data
Mar. 16, 2004 (TW) 093107010

(51) Int. Cl. G06F 15/00; G03F 3/10

(52) U.S. Cl. 358/527; 358/448

(57) ABSTRACT

An apparatus for improving quality of a scanned image through a preview operation has a scanning unit. A method for improving the quality of the scanned image through the preview operation includes driving the scanning unit to scan a medium for generating a plurality of gray levels, generating an average value corresponding to the gray levels, comparing the average value with a predetermined value to set a scanning parameter, and driving the scanning unit to scan the medium according to the scanning parameter.

### BACKGROUND OF INVENTION

1. Field of the Invention

The invention relates to an image processing apparatus and a driving method thereof, and more particularly, to a method for using a preview scanning operation to improve the image quality of a multi-function peripheral.

2. Description of the Prior Art

Generally speaking, a multi-function peripheral (MFP) integrates printers and scanners that were originally implemented separately so that the MFP saves space and reduces costs. As is well known in the art, MFPs are not only equipped with the functions of printing and scanning, but also integrates the function of printing and scanning to perform a copy operation. Please refer to FIG. 1, which is a block diagram of a prior art MFP 10. The MFP 10 comprises a controller 12, a lamp device 14, a charge-coupled device (CCD) 16, an analog frond-end (AFE) 18, a digital image processing unit 20, a print device 22, and an output port 24. The controller 12 is used for controlling operations of the lamp device 14 and the CCD 16, which means that the controller 12 drives the CCD 16 to detect the content of a medium (such as a document) and generate the induced voltage corresponding to a plurality of pixels. The lamp device 14 is used as a light source for the CCD 16 to scan the document. The induced voltage generated by the CCD 16 is outputted to the AFE 18. Then the AFE 18 adjusts the DC offset of the induced voltage of each pixel. After that, the AFE 18 amplifies the induced voltage according to a gain, and finally transforms the modified induced voltage (analog signal) into a corresponding gray level (digital signal) according to a voltage-to-gray-level transformation relation. That is to say, the AFE 18 sends the gray level of each pixel in the document to the digital image processing unit 20. Therefore, the digital image processing unit 20 stores the gray levels corresponding to the pixels in the document, and continues the following operation according to an activated function of the MFP 10. For example, when a user uses the MFP 20 to scan a document, the digital image processing unit 20 generates an image datum according to gray levels of the pixels in the document, and outputs the image datum to a computer through the output port 24 (e.g. an USB interface). On the other hand, if the user controls the MFP 10 to copy a document, the digital image processing unit 20 outputs the above image datum to the print device 22 so that the print device 22 will transform the image datum into corresponding print datum and then print the print datum on a piece of paper. Thus the copying operation of the document is completed.

When the prior art MFP 10 activates the scanning or copying operations, it first drives the CCD 16 to preview the document waiting to be processed. The preview operation is used for determining the information of the document, such as size and position, so that the controller 12 controls the CCD 16 to scan the document quickly with a smaller resolution. When the CCD 15 performs the scanning and copying operations corresponding to the document, the controller 12 controls the CCD 16 to scan the document with a larger resolution. For example, the controller 12 controls the CCD 16 to scan the document generated by the digital image processing unit 20 with a 600 DPI resolution to record the content (graphics or words) of the corresponding document.

High resolution (e.g. 1200 DPI) and high speed transmission interface (e.g. an USB 2.0 interface) result in the smaller size and shorter time of exposure of the CCD 16, which means that the induced voltage of the corresponding pixels is getting smaller so that the following AFE 18 has to increase the gain so as to amplify the induced voltage. Since the induced voltage is easily distorted in the amplifying process and the final image data processed by the image processing unit 20 might be influenced, the user must adjust the MFP 10 after the computer outputs the image scanned by the MFP 10 through a display device or after the print device 22 prints the image scanned by the MFP 10. For example, the user is asked to adjust the brightness and the contrast of image through a user interface, but it is not convenient for the user to set up the MFP 10 manually through the user interface. Moreover, the user has to set up the MFP 10 according to the output result after the scanning and copying operations, which results in a low efficiency of the scanning and copying operations performed by the MFP 10. Additionally, the MFP 10 consumes unnecessary ink and toner in the event of an unfavorable printing result.

### SUMMARY OF INVENTION

One objective of the claimed invention is therefore to provide a method and a multi-function peripheral using a preview scanning operation to improve the image quality, to solve the above-mentioned problems.

According to an exemplary embodiment of the claimed invention, a method for driving an image processing apparatus having a scan unit is disclosed. The method comprises: (a) driving the scan unit to scan a medium to generate a plurality of gray levels; (b) generating a corresponding average value according to the plurality of gray levels; (c) comparing the average value with a predetermined value, wherein, if the average value is larger than the predetermined value, setting up a scan parameter corresponding to a first exposure amount, and if the average value is not larger than the predetermined value, setting up the scan parameter corresponding to a second exposure amount; and (d) driving the scan unit to scan the medium according to the scan parameter.

According to another exemplary embodiment of the claimed invention, an image processing apparatus is disclosed comprising: a scan unit used for scanning a medium to generate a plurality of gray levels; a control circuit electrically coupled to the scan unit and used for driving the scan unit comprises a processing unit used for generating a corresponding average value according to the plurality of gray-scale value, and a comparing unit electrically coupled to the processing unit and used for comparing the average value and a predetermined value; wherein, if the average value is larger than the predetermined value, the comparing unit sets up a scan parameter corresponding to a first exposure amount, and if the average value is not larger than the predetermined value, the comparing unit sets up the scan parameter corresponding to a second exposure amount; and a driving unit electrically coupled to the comparing unit and used for driving the scan unit to again scan the medium according to the scan parameter.

According to another exemplary embodiment of the claimed invention, a method for driving a image processing apparatus having a detecting unit is disclosed. The method comprises: (a) driving the scan unit to scan the medium to generate a plurality of gray levels; (b) determining the recorded content according to the plurality of gray levels, wherein if the content recorded in the medium comprises no picture, setting up a scan parameter corresponding to a first exposure amount, and if the content recorded in the medium comprises a picture, setting up the scan parameter corresponding to a second exposure amount; and (c) driving the scan unit to scan the medium according to the scan parameter.

According to another exemplary embodiment of the claimed invention, an image processing apparatus is disclosed comprising: a scan unit used for scanning the medium to generate a plurality of gray levels; a processing unit used for determining the content recorded in the medium according to the plurality of gray levels, wherein if the content recorded in the medium comprises no picture, the processing unit sets up the scan parameter corresponding to a first exposure amount, and if the content recorded in the medium comprises a picture, the processing unit sets up the scan parameter corresponding to a second exposure amount; and a driving unit electrically coupled to the processing unit and used for driving the scan unit to scan the medium according to the scan parameter again.

Since the present invention improves the image output quality through automatically adjusting the scan parameter, users do not need to adjust any scan parameter manually through a user interface so that users will easily use the scanning and copying functions supported by the MFP. Moreover, the present invention method and apparatus for improving the image printing quality promote the efficiency of the scanning and copying operations of the MFP, which also reduce consumes of ink and toner because users do not have to adjust the MFP according to the output image result after the MFP has finished the scanning and copying operations.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a block diagram of a prior art MFP.

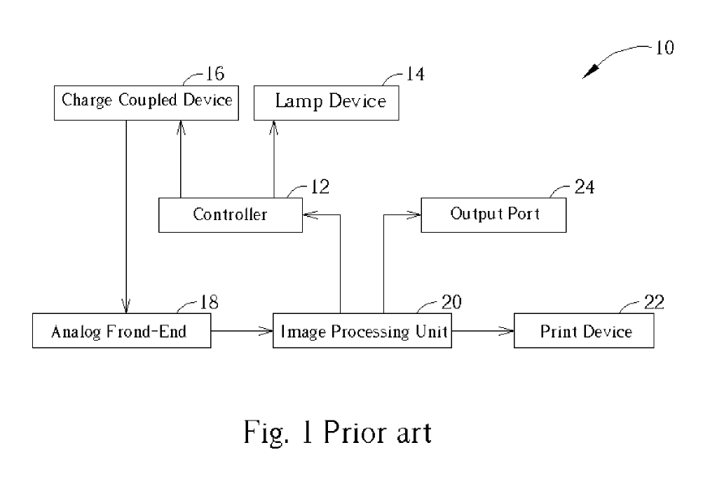

FIG. 2 is a block diagram of a first MFP according to the present invention.

FIG. 3 is a flowchart of a first method of improving the output image quality according to the present invention.

FIG. 4 is a flowchart of a second method of improving the output image quality according to the present invention.

FIG. 5 is a block diagram of a second MFP according to the present invention.

FIG. 6 is a flowchart of a third method of improving the output image quality according to the present invention.

### DETAILED DESCRIPTION

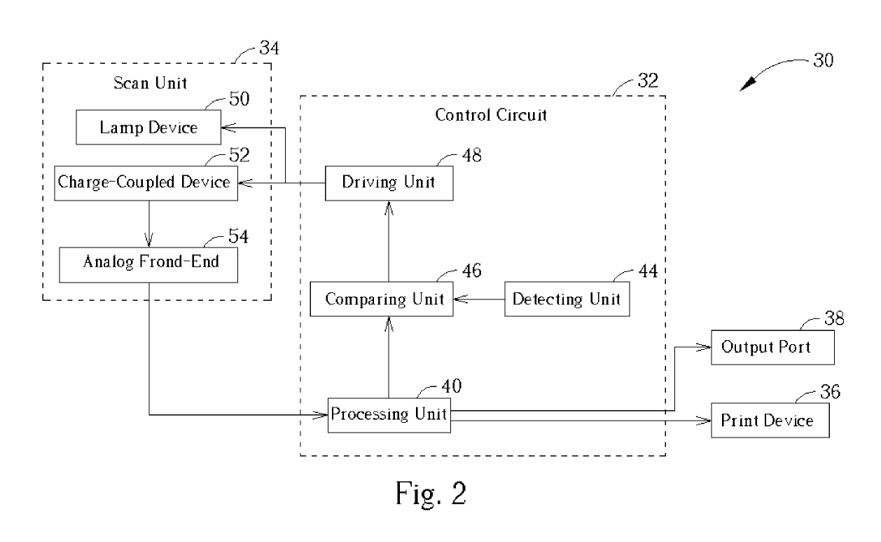

Please refer to FIG. 2. FIG. 2 is a block diagram of a first MFP 30 according to the present invention. The MFP 30 comprises a control circuit 32, a scan unit 34, a print device 36, and an output port 38. The control circuit 32 comprises a processing unit 40, a detecting unit 44, a comparing unit 46, and a driving unit 48. The scan unit 34 comprises a lamp device 50, a CCD 52, and an AFE 54. The control circuit 32 is used for controlling the scan unit 34 to perform the scanning operation, and the lamp device 50 is used for providing the CCD 52 with the required light source so that the CCD 52 generates the induced voltage corresponding to each pixel and outputs the induced voltage to the AFE 54 when the lamp device 50 shines on the content of a medium (e.g. a document waiting to be processed). As mentioned above, the AFE 54 transforms the induced voltage of each pixel into corresponding gray level, and outputs the gray level to the processing unit 40. The processing unit 40 generates the image data corresponding to the document according to the gray levels outputted by the AFE 54. When the MFP 30 activates the scanning operation, the image data are transmitted to a computer through output port 38, and when the MFP 30 activates the copying operation, the image data are transmitted to the print device 36, which transforms the print data into print data so as to print it on a piece of paper. Additionally, the processing unit 40 calculates the average value of the gray levels of the pixels, and the detecting unit 42 detects either the scanning operation or the copying operation that the MFP 30 performs and informs the comparing unit 46. The comparing unit 46 compares the average value outputted by the processing unit 40 with a predetermined value to set up a scanning parameter. For example, the parameter defines the total exposure time when scanning the document, the number of lamps that the lamp device 50 activates, and the brightness of the lamps in the lamp device 50. That is to say, the scanning parameter is used for setting up the exposure amount of the CCD 52. Finally, the driving unit 48 drives the CCD 52 to perform the scanning operation according to the adjusted parameter.

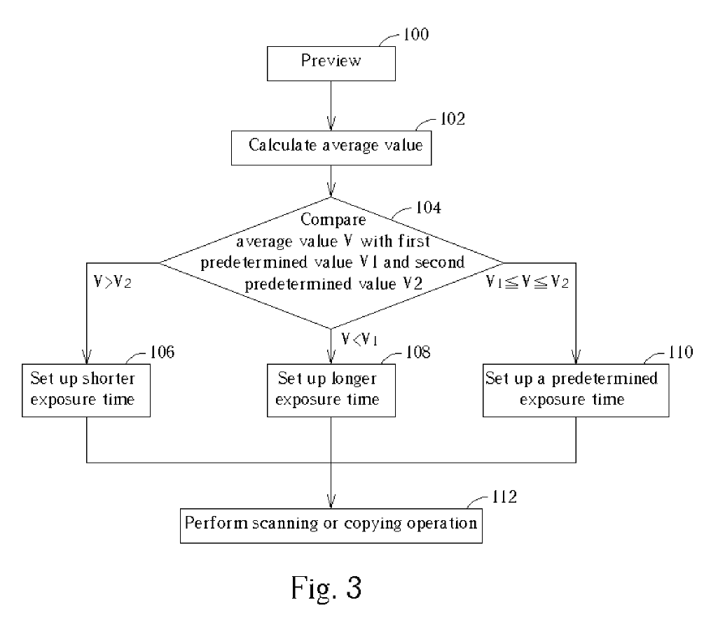

Please refer to FIG. 3. FIG. 3 is a flowchart of the first method of improving the output image quality according to present invention. The first method of improving the output image quality according to present invention is applied to the MFP 30 shown in FIG. 2, and the operational steps are illustrated below. First, the driving unit 48 drives the CCD 52 to preview a document needed to be processed (step 100), which means that the CCD 52 scans the document roughly with a lower resolution, and generates the induced voltages corresponding to a plurality of pixels to the AFE 54. Then the AFE 54 processes the received induced voltages and outputs the gray levels corresponding to the pixels to the processing unit 40. In the present invention, the processing unit 40 calculates the average value V of the gray levels corresponding to the pixels (step 102), and outputs the average value V to the comparing unit 46.

Afterwards, the comparing unit 46 compares the average value V with a first predetermined value V1 and a second predetermined value V2 (step 104), respectively, wherein the first predetermined value V1 and the second predetermined value V2 are used for defining a tolerable range, which means that the first predetermined value V1 is the lower bound of the tolerable range, and the second predetermined value V2 is the upper bound of the tolerable range. If the average value V is larger than the second predetermined value V2, which means that the CCD 52 is over exposed during the preview operation, the comparing unit 46 will adjust the driving unit 48 to control the scanning parameter that the CCD 52 uses according to the comparison result. As shown in FIG. 3, the comparing unit 46 will shorten the total exposure time of the CCD 52 (step 106) so that the image recorded by the processing unit 40 will not be over exposed when the CCD 52 scans the document formally so as to accomplish the scanning and copying operations the user activates (step 112). Additionally, if the average value V is smaller than the first predetermined value V1, which means that the CCD 52 is insufficiently exposed, the comparing unit 46 will adjust the driving unit 48 to control the scanning parameter the CCD 52 uses according to the comparison result. As shown in FIG. 3, the comparing unit 46 will increase the total exposure time of the CCD 52 (step 108) so that the image recorded by the processing unit 40 will not be insufficiently exposed when the CCD 52 scans the document formally so as to accomplish the scanning and copying operations the user activates (step 112). Moreover, if the average value V lies between the first and second predetermined values V1 and V2, which means that the CCD 52 is appropriately exposed, the compare 46 will adjust the driving unit 48 to control the scanning parameter the CCD 52 uses according to the comparison result. As shown in FIG. 3, the comparing unit 46 sets up a predetermined exposure time as that of the CCD 52 (step 110), wherein the predetermined exposure time is between those mentioned in steps 106 and 108, so that the image recorded by the processing unit 40 will have great image quality because of the appropriate predetermined exposure time when the CCD 52 scans the document formally so as to accomplish the scanning and copying operations the user activates (step 112).

Please note that besides the exposure time, the brightness and number of lamps in the lamp device 50 also influence the exposure amount of the CCD 52, which means that the brighter the lamps are and the more lamps it has will definitely increase the exposure amount. Therefore, the method of improving the image quality outputted in the present invention is capable of adjusting the brightness and the number of lamps to adjust the exposure time. For example, step 106 can be replaced by increasing the brightness of lamps, step 108 can be replaced by reducing the brightness of the lamps, and step 110 can be replaced by using a predetermined brightness of lamps. In another example, step 106 can be replaced by increasing the number of lamps, step 108 can be replaced by reducing the number of lamps, and step 110 can be replaced by using a predetermined number of lamps. All the above embodiments using the preview operation to calibrate the exposure amount are included in the category of the present invention.

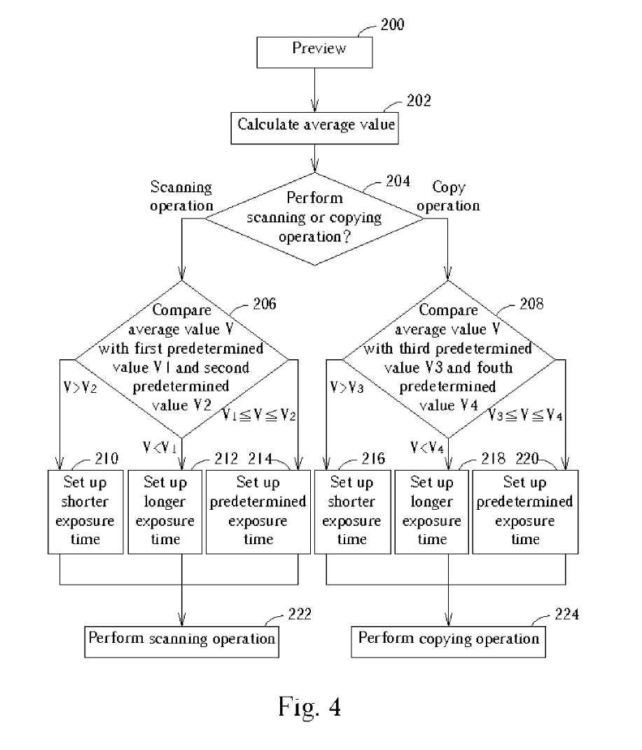

Please refer to FIG. 4. FIG. 4 is a flowchart of a second method of improving the output image quality according to present invention. The second method of improving the output image quality according to present invention is applied to the MFP 30 shown in FIG. 2. The steps of the operation are illustrated below. First, the driving unit 48 drives the CCD 52 to preview a document required to be processed (step 200), which means that the CCD 52 scans the document roughly with a lower resolution and generates the induced voltages corresponding to a plurality of pixels to the AFE 54. Then the AFE 54 processes the received induced voltages and outputs the gray levels corresponding to the pixels to the processing unit 40. Meanwhile, the processing unit 40 calculates the average value V of the gray levels corresponding to the pixels (step 202), and outputs the average value V to the comparing unit 46.

In this embodiment, the detecting unit 44 detects which function the MFP 30 has been activated (step 204). For example, when the user desires to scan a document, the user will press the “SCAN” button on the housing of the MFP 30, and when the user desires to copy a document, the user will press the “COPY” button on the housing of the MFP 30, so that the detecting unit 44 will be informed that either the scanning operation or the copying operation of the MFP 30 has been activated. As mentioned above, the copying operation includes the scanning and copying operations. Thus for scanning and copying operations, the two operations correspond to different operation processes so that the image generated after the scanning operation or the copying operation will be of the best quality if appropriate scanning parameters are set up separately according to the scanning and copying operations. For example, the CCD 52 receives an increased exposure amount during the copying operation because of the scanning parameter applied so as to make the print device 66 to print the image with a better quality compared with a scanning operation at the same resolution. Therefore, when the MFP 30 activates the scanning operation, the detecting unit 44 informs the comparing unit 46 so that the comparing unit 46 compares the average value with a first predetermined value V1 and a second predetermined value V2 (step 206). Additionally, when the MFP 30 activates the copying operation, the detecting unit 44 informs the comparing unit 46 so that the comparing unit 46 compares the average value V with a third predetermined value V3 and a fourth predetermined value V4 (step 208), wherein the range defined by the first predetermined value V1 and the second predetermined value V2 is different from that defined by the third predetermined value V3 and the fourth predetermined value V4. In other words, the intention of adjusting the scanning parameters of the scanning and copying operations separately is therefore accomplished in this embodiment through step 204.

The operation principles of steps 210, 212, and 214 are the same as those of steps 106,108, and 110, and the operation principles of steps 216, 218, and 220 are the same as those of steps 106, 108, and 110. Finally, when the CCD 52 scans the document formally so as to accomplish the scanning and copying operations activated by the user (steps 222, 224), the driving unit 48 will have the scanning and copying operations to have fine image quality and printing quality according to the exposure time set up in steps 210, 212, 214, 216, 218, and 220. As mentioned above, in addition to the exposure time, the brightness and the number of lamps in the lamp device 50 influence the exposure amount of the CCD 52, which means that the brighter the lamps are and the more lamps used, the greater the exposure amount of the CCD 52 is. Thus the method of improving the image quality of the present invention may also be accomplished by adjusting the brightness or the number of lamps, and using the information provided from the preview operation to calibrate the exposure amount of the CCD 52.

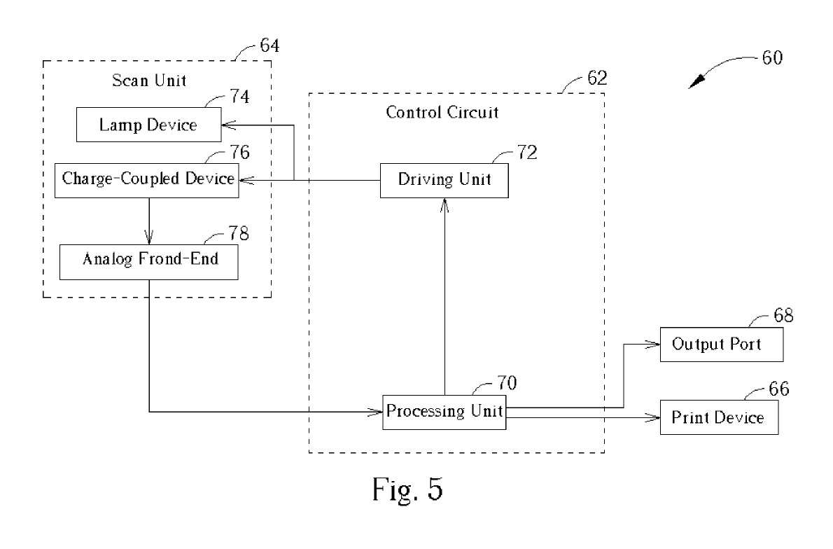

Please refer to FIG. 5. FIG. 5 is a block diagram of a second MFP 60 according to the present invention. The MFP 60 comprises a control circuit 62, a scan unit 64, a print device 66, and an output port 68. The control circuit 62 includes a processing unit 70 and a driving unit 72. The scan unit 64 comprises a lamp device 70, a CCD 76, and an AFE 78. The difference between the MFP 60 and the MFP 30 is the processing unit 70 while the other elements have the same function. In this embodiment, the processing unit 70 does not calculate the average value of the gray levels corresponding to the pixels generated from the AFE 78, but instead determines whether the content of the document waiting to be processed is pure text or includes graphics according to the gray levels of the pixels. If the content of the document is pure text, the MFP 60 scans the document with a lower resolution. However, if the content of the document includes pictures, then the MFP 60 will have to scan the document with a higher resolution, otherwise the quality of the picture may be poor because of insufficient resolution.

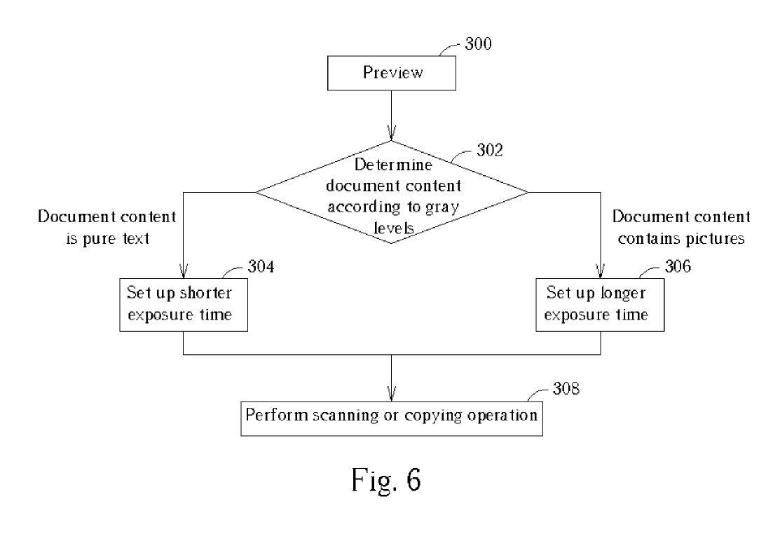

Please refer to FIG. 6. FIG. 6 is a flowchart of a third method of improving the output image quality according to the present invention. The third method of improving the output image quality according to present invention is applied to the MFP 60 shown in FIG. 5, and the steps of operation are illustrated below. First, the driving unit 72 drives the CCD 76 to perform the preview operation to a document required to be processed (step 300), which means that the CCD 76 scans the document roughly with a lower resolution and generates the induced voltage corresponding to a plurality of pixels to the AFE 78. Then the AFE 78 processes the received induced voltages and outputs the gray levels corresponding to the pixels to the processing unit 70. Moreover, the processing unit 70 determines whether the content of the document is pure text or has pictures included according to the information provided from the gray levels of the pixels (such as the distribution of gray levels) (step 302). When the driving unit 72 drives the CCD 76 to scan the document with a higher resolution, the total exposure time of the CCD 76 should be longer so as to receive enough exposure during the scanning operation. On the contrary, when the driving unit 72 drives the CCD 76 to scan the document with a lower resolution, the total exposure time of the CCD 76 should be shorter during the scanning operation. As mentioned above, if the content of the document is pure text, the MFP 60 may scan the document with a lower resolution so that the processing unit 70 can set up the scanning parameter to have shorter exposure time to accomplish the process of scanning the document (step 304). However, if the document contains pictures, the MFP 60 needs to scan the document with a higher resolution, which means that processing unit 70 will set up the scanning parameter to a longer exposure time so as to accomplish the scanning operation (step 306). Please note that the MFP 60 scans the document with a resolution higher than that in the preview operation. If the user controls the MFP 60 to perform the scanning operation, the processing unit 70 generates an image data according to the gray levels corresponding to the pixels in the document, and outputs the image data to a computer through the output port 68 to finish the scanning operation. Furthermore, if the user controls the MFP 60 to perform the copying operation, the processing unit 70 outputs the image to the print device 77 so that the print device 66 transforms the image data into printing data, and prints the printing data on a piece of paper. The copying operation is thus completed.

Compared with the prior art, the method and apparatus of the present invention capable of improving the image output quality utilize the information provided from the preview operation to determine the condition of exposure amount of the CCD, and adjust the scanning parameter appropriately according to the activated function of scanning operation or copying operation. Additionally, the method and apparatus of the present invention disclose utilizing the information provided from the preview operation to determine the scanning parameter according to the content. Since the method and apparatus provided in the present invention improves the image output quality by adjusting the scanning parameter automatically, the user does not need to adjust the scanning parameter manually through a user interface so that it is convenient for the user to use the scanning and copying functions of the MFP. Moreover, the user does not need to adjust the settings of the MFP according to the outputted image results after the MFP has finished the scanning and copying operations. Thus the method and apparatus the present invention improves the efficiency of the scanning and copying operations of MFP, and reduces the consumption of ink and toner.

Those skilled in the art will readily observe that numerous modifications and alterations of the device may be made while retaining the teachings of the invention. Accordingly, the above disclosure should be construed as limited only by the metes and bounds of the appended claims.

1. A method for driving an image processing apparatus having a scan unit, the method comprising:
(a) driving the scan unit to scan a medium to generate a plurality of gray levels;
(b) generating a corresponding average value according to the gray levels;
(c) comparing the average value with a predetermined value, wherein, if the average value is larger than the predetermined value, setting up a scan parameter corresponding to a first exposure amount, and if the average value is not greater than the predetermined value, setting up the scan parameter corresponding to a second exposure amount; and
(d) driving the scan unit to scan the medium according to the scan parameter.

2. The method of claim 1, wherein in step (c), the first exposure amount is greater than the second exposure amount.

3. The method of claim 1, wherein step (c) further comprises:
if the average value is greater than the predetermined value, setting up the scan parameter to record a first lamp brightness value; and
if the average value is not greater than the predetermined value, setting up the scan parameter to record a second lamp brightness value.

4. The method of claim 3, wherein the first lamp brightness value is greater than the second lamp brightness value.

5. The method of claim 1, wherein step (c) further comprises:
if the average value is greater than the predetermined value, setting up the scan parameter to record a first lamp activation number; and
if the average value is not greater than the predetermined value, setting up the scan parameter to record a second lamp activation number.

6. The method of claim 5, wherein the first lamp activation number is larger than the second lamp activation number.

7. The method of claim 1, wherein step (c) further comprises:
if the average value is greater than the predetermined value, setting up the scan parameter to record a first exposure time; and
if the average value is not greater than the predetermined value, setting up the scan parameter to record a second exposure time.

8. The method of claim 7, wherein the first exposure time is longer than the second exposure time.

9. The method of claim 1, wherein step (a) further comprises driving the scan unit to scan the medium with a first resolution, and step (d) further comprises driving the scan unit to scan the medium with a second resolution, wherein the second resolution is higher than the first resolution.

10. The method of claim 1, further comprising:
(e) detecting either a first predetermined function or a second predetermined function activated in the image processing apparatus so as to set up the predetermined value.

11. The method of claim 10, wherein in step (e), the first predetermined function is the scanning function, and the second predetermined function is the copying function.

12. An image processing apparatus comprising:
a scan unit used for scanning a medium to generate a plurality of gray levels; and
a control circuit electrically coupled to the scan unit and used for driving the scan unit, the control circuit comprising:
a processing unit used for generating a corresponding average value according to the gray levels;
a comparing unit electrically coupled to the processing unit and used for comparing the average value with a predetermined value, wherein, if the average value is greater than the predetermined value, the comparing unit sets up a scan parameter corresponding to a first exposure amount, and if the average value is not greater than the predetermined value, the comparing unit sets up the scan parameter corresponding to a second exposure amount; and
a driving unit electrically coupled to the comparing unit and used for driving the scan unit to again scan the medium according to the scan parameter.

13. The image processing apparatus of claim 12, wherein the first exposure amount is greater than the second exposure amount.

14. The image processing apparatus of claim 12, wherein the scan unit scans the medium with a first resolution, and the driving unit drives the scan unit to scan the medium with a second resolution; the second resolution being greater than the first resolution.

15. The image processing apparatus in claim 12, wherein the control circuit further comprises:
a detecting unit electrically coupled to the comparing unit and used for detecting either a first predetermined function or a second predetermined function activated in the image processing apparatus so as to set up the predetermined value.

16. The image processing apparatus in claim 15, wherein the first predetermined function is the scanning function of scanning, and the second predetermined function is the copying function.

17. A method for driving an image processing apparatus having a detecting unit, the method comprising:
(a) driving the scan unit to scan the medium to generate a plurality of gray levels;
(b) determining the recorded content according to the gray levels, wherein, if the content recorded in the medium comprises no picture, setting up a scan parameter corresponding to a first exposure amount, and if the content recorded in the medium comprises a picture, setting up the scan parameter corresponding to a second exposure amount; and
(c) driving the scan unit to scan the medium according to the scan parameter.

18. The method of claim 17, wherein in step (b), the first exposure amount is greater than the second exposure amount.

19. The method of claim 17, wherein step (b) further comprises:
if the content recorded in the medium comprises no picture, setting up the scan parameter to record a first lamp brightness value; and
if the content recorded in the medium comprises a picture, setting up the scan parameter to record a second lamp brightness value.

20. The method of claim 19, wherein the first lamp brightness value is smaller than the second lamp brightness value.

21. The method of claim 17, wherein step (c) further comprises:
if the content recorded in the medium comprises no picture, setting up the scan parameter to record a first lamp activation number; and
if the content recorded in the medium comprises a picture, setting up the scan parameter to record a second lamp activation number.

22. The method of claim 21, wherein the first lamp activation number is smaller than the second lamp activation number.

23. The method of claim 17, wherein step (c) further comprises:
if the content recorded in the medium comprises no picture, setting up the scan parameter to record a first exposure time; and
if the content recorded in the medium comprises a picture, setting up the scan parameter to record a second exposure time.

24. The method of claim 23, wherein the first exposure time is shorter than the second exposure time.

25. The method of claim 17, wherein step (a) further comprises driving the scan unit to scan the medium with a first resolution, and step (c) further comprises driving the scan unit to scan the medium with a second resolution; wherein the second resolution is greater then the first resolution.

26. An image processing apparatus comprising:
a scan unit used for scanning the medium to generate a plurality of gray levels;
a processing unit used for determining the content recorded in the medium according to the gray levels, wherein, if the content recorded in the medium comprises no picture, the processing unit sets up a scan parameter corresponding to a first exposure amount, and if the content recorded in the medium comprises a picture, the processing unit sets up the scan parameter corresponding to a second exposure amount; and
a driving unit electrically coupled to the processing unit and used for driving the scan unit to again scan the medium according to the scan parameter.

27. The image processing apparatus in claim 26, wherein the first exposure amount is greater than the second exposure amount.

28. The image processing apparatus in claim 28, wherein the scan unit scans the medium with a first resolution, and the driving unit drives the scan unit to scan the medium with a second resolution; wherein the second resolution is greater than the first resolution.
